(19) United States
(12) Patent Application Publication
(10) Pub. No.: US 2002/0117199 A1
(43) Pub. Date: Aug. 29, 2002

(54) Process for producing photovoltaic devices

(76) Inventor: Robert S. Oswald, Mechanicsville, VA (US)

Correspondence Address: BP America Inc., Docket Clerk, Law Department, M.C. 2207A, 200 East Randolph Drive, Chicago, IL, 60601-7125, US

(21) Appl. No.: 10/068,733

(22) Filed: Feb. 6, 2002

Related U.S. Application Data
(60) Provisional application No. 60/266,771, filed on Feb. 6, 2001.

(51) Int. Cl. H01L 31/00

(52) U.S. Cl. 136/256; 136/261; 136/258; 438/96; 438/61

(57) ABSTRACT

A continuous process for depositing a thin film layer or layers on a substrate during the production of thin film photovoltaic devices comprising moving the substrate at an elevated temperature in a reduced pressure environment past one or more sources of material to be deposited thereby forming on the substrate at least one thin film of the material from the source.

### BACKGROUND OF THE INVENTION

This application claims the benefit of U.S. Provisional Application No. 60/266,771, filed

This invention relates to photovoltaic devices, particularly photovoltaic devices comprising thin films of semiconductor materials, such as thin films of amorphous silicon. More particularly, this invention relates to thin film photovoltaic devices comprising amorphous silicon and produced by a continuous or semi-continuous process that provides for the rapid production of such photovoltaic devices in a variety of dimensions suitable for architectural applications such as, for example, windows, building facades and roofs, canopies, awnings and other applications.

It would be very desirable to be able to manufacture photovoltaic devices such that the devices could be used as a readily available, low cost building material. If such photovoltaic devices were available architects and builders would more readily incorporate the photovoltaic devices into the construction of the building. The building facade or roof, for example, could function as a source of renewable electrical power to be used in the operation of the building or for connection to the local grid for use by other electric power consumers. In order to be able to supply photovoltaic devices into this market, the photovoltaic device would need to be made of a versatile material, such as glass, that can also serve as a durable and aesthetically appealing building medium, and in a variety of dimensions to meet the variable needs of architects and builders.

A variety of photovoltaic devices are available commercially. One group of photovoltaic devices is based on crystalline or polycrystalline silicon semiconductor materials. These devices which comprise doped wafers of crystalline or polycrystalline silicon are very efficient in converting light energy into electrical energy, but since they have as their central feature a crystalline or polycrystalline wafer, they are not readily amenable to manufacturing the configurations most desirable for building facades.

Another group of photovoltaic devices available commercially are based on amorphous, thin film semiconductor materials. Thin film photovoltaic devices are generally constructed of amorphous silicon-containing semiconductor films on a substrate. The substrate of the thin film photovoltaic device can be made of glass or a metal, such as aluminum, steel or other metal. Soda-lime glass has been often used as a substrate because it is inexpensive, durable and transparent. If a glass substrate is used, a transparent conductive coating, such as tin oxide (SnO₂) can be applied to the glass substrate prior to forming the amorphous silicon-containing semiconductor films. A metallic contact can be formed on the back of the solar cell The photovoltaic panel or array can be made semitransparent by removing a portion of the back metal contact by, for example, laser scribing. The semitransparent photovoltaic panel or array can then be used a window or even as a roof if a degree of transparency is desired.

The thin film, amorphous silicon-type of photovoltaic devices are excellent candidates for the high volume, economically and aesthetically appealing photovoltaic devices that can be used in architectural applications meeting many of the criteria mentioned above. However, to date, processes for manufacturing thin film photovoltaic devices on glass substrates have been directed to batch-type processes wherein the slow steps in the batch-mode process are the steps of forming the amorphous, semiconductor layers on the glass substrates. Additionally, the vacuum deposition chambers used to apply the amorphous silicon layers to the glass substrates in these batch-mode processes are designed to accommodate only one size piece of glass substrate which is not of a size that would be suitable for all architectural uses. Additionally, because it is a batch-mode type of operation, the ability to mass-produce amorphous, thin-film photovoltaics at lower cost is hampered.

The art, therefore, needs a method of producing thin film photovoltaic devices in a continuous or at least semi-continuous manner where the dimensions of the photovoltaic device can be varied to meet the demands of varied architectural applications, and where the photovoltaic devices can be produced at a cost that will make them highly attractive building materials serving the dual purpose of providing a construction material and a source of renewable electrical power. The present invention provides such a process as well as the apparatus to perform such a process. The present invention also provides new photovoltaic devices that can be manufactured by such processes.

### SUMMARY OF THE INVENTION

A continuous process for depositing a thin film layer or layers on a substrate during the production of thin film photovoltaic devices comprising moving the substrate at an elevated temperature in a reduced pressure environment past one or more sources of material to be deposited thereby forming on the substrate at least one thin film of the material from the source.

### BRIEF DESCRIPTION OF THE DRAWING

FIG. 1 is a cross-sectional view of a monolithic single-junction photovoltaic device that can be made by the present invention.

FIG. 2 is a cross-sectional view of a monolithic tandem junction photovoltaic device that can be made by the present invention.

FIG. 3 is a process flow diagram for producing photovoltaic devices in accordance with principles of the present invention.

FIGS. 4a and 4b combined is a schematic view of an apparatus for the deposition thin film semiconductor layers in accordance with the present invention.

### DETAILED DESCRIPTION OF THE INVENTION

This invention is a process for the production of thin film photovoltaic devices that can, for example, be used in architectural applications such as in building facades, roofs, and in canopies, shades, awnings, and the like. While this invention is not limited to a specific type of thin film photovoltaic device, this invention is particularly suited to the production of thin film photovoltaic devices containing at least one amorphous silicon-containing semiconductor layer, especially an amorphous hydrogenated silicon (a-Si:H) layer. Generally, the thin film photovoltaic device comprises a substrate, preferably a transparent vitreous substrate, a conductive contact on the substrate, one or more semiconductor layers which generate an electric charge separation upon exposure to light, and a second electrically conductive contact. The semiconductor layer or layers are positioned between the electrically conductive contacts. The semiconductor layers are deposited in a manner that provides for a junction and preferably the photovoltaic devices of this invention contain at least one p-i-n or “p-i-n” junction, or at least one n-i-p- or “n-i-p” junction although other types of semiconductor junctions can be utilized. The p-i-n junction can exist in a semiconductor comprising p-, i- and n- regions or layers. The i-region is an intrinsic region, the p- region is typically a positively doped region, and the n- region is typically a negatively doped region.

The i-region is positioned between the p- and n- regions in the p-i-n junction or the n-i-p junction. It is generally understood that when light, for example, solar radiation, impinges on a photoelectric device containing a p-i-n junction, electron-hole pairs are generated in the i-region. The “holes” from the generated pair flow toward the n- region and the electrons from the generated pair flow toward the p-region. The contacts are generally directly or indirectly in contact with the p- and n-regions or layers. Current will flow through an external circuit connecting these contacts as long as light continues to impinge on the photoelectric device thereby generating the electron-hole pairs.

In the process of this invention the substrate used to form the photovoltaic devices of this invention can be any suitable substrate for receiving the electrically conductive contact and semiconductor layers of the photovoltaic device. The substrate is generally flat and can be glass, such and soda-lime glass or a low iron glass, a plastic such as a polyimide, or a metal film such as aluminum, steel, titanium, chromium, iron, and the like. Glass, particularly a highly transparent or transmissive glass is preferred. As will be discussed in greater detail herein below, a low iron glass is the preferred substrate. The substrate can be in any size and shape provided it can fit into the processing equipment used in the process of this invention. If larger substrate sizes are desired, the processing equipment as described herein will need to be sized accordingly. Generally, however, for most architectural applications, the substrate will be made of glass and will range in size from about 10 square feet to about 200 square feet and will be preferably be either rectangular or square in shape, although the exact shape is not limited. One of the features of the process of this invention is the ability to have a range or variety of substrate shapes and sizes without changing the processing apparatus. Thus, the process of this invention can be used to manufacture photovoltaic devices suitable, for example, for specific architectural applications. The thickness of the substrate is also variable and will, in general, be selected in view of the application of the photovoltaic device. If for example the photovoltaic device uses glass as the substrate, the thickness of the glass can range in thickness from 0.088 inches to about 0.500 inches, more preferably from about 0.125 inches to about 0.250 inches. If the glass will be used in large dimensions, such as for example, at least about 60, or at least about 200 square feet, the glass will preferably have a thickness of at least about 0.125 inches, more preferably of at least about 0.187 inches. When the glass substrate has a thickness of at least about 0.187 inches or at least about 0.250 inches, it will preferably be a low iron glass. By low iron we mean, preferably, that the glass has no more than about 0.1 wt % iron, more preferably less than about 0.1 wt % iron.

As set forth above, the process of this invention is a continuous or at least a semi-continuous process for preparing thin film photovoltaic devices. By continuous we mean a process whereby the substrate moves continuously along on a belt, on rollers, jig, moving framework, or other means for conveying the substrate from one operation or step in the process to the next operation or step. The means for conveying the substrate can comprise two or more different ways of conveying the substrate. The substrate can move horizontally or vertically, or nearly vertically (e.g. ±10° from vertical) through the process.

It is preferable that the process of this invention be completely continuous in that the means for conveying the substrate conveys the substrate to and through each step or individual operation in the overall process. However, it is not necessary for the process of this invention to be completely continuous. One or more steps can be completed in a manner isolated from the rest of the processes or in what is many times referred to as a batch-type of process step. When one or more (but not all) process steps are conducted so that it is isolated from the rest of the process steps, the overall process is referred to herein as a semi-continuous process.

The process of this invention will now be described utilizing glass as the substrate material. However, it is to be understood that the invention is not so limited, and any of the above mentioned or other suitable substrates can be used.

In this embodiment using glass as the substrate, the glass, preferably flat glass, and preferably low iron glass, is obtained from a glass vendor. Preferably the glass is supplied in the desired size and shape with the edges seamed, and heat treated to enhance the strength of the glass. However, optionally, the glass can be supplied without such treatment and the first step of the process of this invention would be to prepare the glass by cutting it to the desired shape, seam the edges to provide for crack resistance and to heat strengthen the glass. Heat strengthening can take place either before or after the cutting and before or after the seaming procedure. Preferably the heat strengthening is conducted after the cutting and the seaming of the glass. Another step in the process is to apply a conductive strip or strips which function as electrical conduits or wires from the photovoltaically active portions of the photovoltaic device to, preferably, a central location, so the photovoltaic device can be connected to the device or system using the electric current generated by the photovoltaic device. The connection is suitably made by soldering an external wire or applying an electrical connector to the ends of conducive strips or bus bars. Such conductive strips can be a wire in any shape such as for example a flat tape and can be made of any material that is electrically conductive, durable and can withstand the further processing conditions of the process of this invention if the conductive strips are added to the substrate as one of the initial steps in the process. Such means for conducting electrical current is preferably firmly bound or bonded to the substrate so that it does not separate during later processing steps or when the photovoltaic device is in service. Highly suitable conductive strips can be added to the substrate as a fritted conductive paste comprising a fritted metal such as silver, copper, tin, nickel, antimony or combinations of one or more thereof. The paste also typically comprises an organic solvent that will evaporate when heated and one or more organic binders which will burn or evaporate when the paste is heated to a sufficiently high temperature. The fritted paste can be deposited on the glass substrate in Ea desired pattern by a suitable paste-dispensing machine. The paste can be applied to the substrate in the desired width so that when the substrate containing the paste is heated to the proper temperature to evaporate the solvent and burn or evaporate the organic binder, a durable conductive strip is formed. Thus, in the process of this invention the conductive strip is preferably applied to the substrate by depositing on the glass substrate a fritted conductive paste using, for example a paste dispenser or other means for depositing a paste material in the desired pattern and subsequently heating or curing the paste in a furnace or oven at an elevated temperature such as for example about 50° C. to about 600° C., more preferably about 100° C. to about 500° C., and for a time sufficient to cure the paste and form a conductive strip means. This can also be done during the glass strengthening process. This heating step could also be used to anneal the back contact of the solar cell if the frit wiring temperature is less than about 250° C. U.S. Pat. No. 5,593,901, which is incorporated herein in its entirety, describes conductive pastes and methods for adding them to a substrate to form bus bars and conductive strips useful in the method and photovoltaic devices of this invention.

The invented process comprises applying a front contact to the substrate. Optionally, the substrate is washed and dried before the front contact is applied Washing is accomplished using soap and/or deionized water as a washing medium, for example, applied as a high power spray, or by submerging the substrate in a bath of the washing medium and optionally applying agitation to the bath or some other means for inducing a washing or cleaning of the substrate. Ultrasonic cleaning is also suitable. The substrate is preferably rinsed to remove the cleaning medium and then dried by a means for drying the substrate such as for example hot air, blowing with air, or other means for drying the substrate.

The front contact comprises one or more layers of a suitable transparent conductive material. Typically, the front contact comprises one or more transparent doped conductive oxides (CTO or TCO) such as tin oxide, indium-tin oxide, zinc oxide, or cadmium stannate. In the process of this invention, the preferred front contact comprises doped zinc oxide. Prior to depositing the front contact on the substrate, silicon dioxide or other transparent dielectric substance can be deposited on the substrate. The dielectric substance, if applied, is generally deposited in a layer about 100 to about 2,000 Å thick, more preferably about 500 to about 1000 Å. The dielectric substance can be applied by physical vapor deposition (PVD) (rf sputtering, reactive sputtering), low-pressure chemical vapor depositions.

The front contact preferably comprising a CTO and most preferably zinc oxide, is deposited to a thickness that provides for a durable and effective front contact. Typically, it is deposited to thickness of about 4,000 to about 12,000 Å, more preferably about 800 to about 10,000A. The front contact is deposited by one or more methods such as chemical vapor deposition (CVD), low pressure chemical vapor deposition (LPCVD), PVD or by one or more sputtering techniques such a sputtering a metal oxide target or a metal target in an oxygen atmosphere. LPCVD of zinc oxide can be accomplished by directing at the substrate a mixture of a reactive zinc compound such as a dialkyl zinc, for example, idiethyl zinc, and water, optionally in the presence of a dopant such as diborane. The reactive zinc compound reacts with the water to form zinc oxide in situ and is deposited on the substrate. Combining LPCVD and PVD can be used to optimize the morphology for the zinc oxide. The morphology of the zinc oxide can also be optimized by reactive ion etching. As will be discussed in greater detail below, in the preferred process of this invention the deposition of the first contact is conducted in a continuous manner as the substrate moves next to, preferably under the source of the front contact material. The deposition is suitably conducted at a rate of about 0.5 Å per second to about 1,000 Å per second thickness, more preferably at a rate of about 1 Å per sec to about 500 Å per second when the substrate is moving by the source of front contact at a rate of about 0.1 meter per minute to about 4 meters per minute, more preferably about 1 meter per minute to about 2 meters per minute. It is preferable to deposit the front contact layer, preferably zinc oxide, on the substrate at a temperature of about 100° C. to about 450° C., more preferably about 150° C. to about 250° C., and at a pressure of about 0.5 milliTorr to about 4 Torr, more preferably about 2 milliTorr to about 2.5 Torr. As will be discussed in more detail herein below, it is advantageous in the process of this invention to deposit the front contact, the semiconductor layer or layers and the first layer of the rear contact at relatively similar temperatures (e.g. ±20° C.) and pressures (e.g. ±5 Torr). In this manner the temperature of the substrate need not be altered, at least not to a great extent, between process steps thereby providing for a rapidly operating continuous process. Also, if the pressures are relatively similar for each such process step, the operations of front contact deposition, semiconductor deposition, and the rear contact deposition can take place in a continuous operation without the time consuming need to make major changes in temperature or pressure. For example if the operation of depositing the front contact, semiconductor layers and the rear contact are conducted at relatively the same temperatures and pressures, these process steps can take place in a production apparatus that is connected such that a substrate on which the deposition is taking place can move through the apparatus in a continuous manner wherein the front contact, semiconductor layers, and the rear contact are deposited in a continuous, sequential and rapid manner without appreciable delay between the deposition steps. The front contact, preferably a CTO, and more preferably zinc oxide, is preferably textured. Most preferably, the texturing or morphology is such that it improves the light scattering of the front contact. Preferably, the front contact has a transmission of at least about 75%, more preferably at least about 80%, and most preferably at least about 85%. The texturing or morphology can be provided during the deposition process or can be accomplished after the deposition for example by one or more etching techniques such as etching by reactive ion etching or by acid immersion.

The front contact is divided or patterned to provide for the cell pattern of the photovoltaic module. This is preferably accomplished by removing strips of the deposited front contact. For example, these strips or scribes can be about 30 micrometers to about 150 micrometers wide, preferably from about 40 micrometers to about 80 micrometers wide and suitably spaced about 0.5 cm to about 2.5 cm, more preferably about 0.8 cm to about 1.2 cm from each other. The spacing of these strips will determine the width of the individual cells on the photovoltaic device. Typically, the strips of removed front contact run from near one edge of the substrate to the opposite edge, for example, from about 0.5 cm to about 2.0 cm from the edge of the substrate. The, strips, however, can extend to the edge of the substrate. The strips are typically parallel to one another, are typically straight, and typically parallel to the edge of the substrate. If the substrate is rectangular, these strips preferably run parallel to an edge of the substrate.

To form these strips in the front contact, the front contact material can be removed by any suitable method such as chemical etching, laser ablation or mechanical stylus. However, in the continuous or semi continuous process of this invention the front contact material is preferably removed by laser scribing. In this method, one or more laser beams are directed at the substrate and scanned across the surface of the front contact material thereby removing the front contact material in the desired pattern.

The laser selected as well as the wavelength of the laser light, the pulse-width of the laser, the laser beam shape and the repetition rate are selected to efficiently remove the front contact in the region of the strips. For example, if the front contact is the preferred zinc oxide, the laser is preferably an excimer, i.e., KrF, ArCl, Nd:YAG, Nd:YLF, or Nd:YVO₄, laser operating at a wavelength of about 200 nanometers to about 1,200 nanometers and suitably at a pulse-width of about 1 nanosecond to about 500 nanoseconds, more preferably of about 5 to about 100 nanoseconds, a repetition rate suitably of about 10 KHz to about 400 KHz more preferably about 30 KHz to about 200 KHz, a beam shape that is suitably top hat, delta function, or gaussian. Preferably it is gaussian. It is preferable to scan the surface of the front contact to form the strips at rate that is about 0.1 meters/second to about 50 meters/second more preferably about 0.8 meters/second, to about 20 meters/second. At these scanning rates, the front contact can be removed to form the strips in a time period that is suitable for the continuous or semi-continuous processes of this invention.

In the preferred process of this invention, the laser scribing to form the strips or scribes in the front contact is conducted at the same or about the same temperature and at the same pressure or about the same pressure as the temperature and pressure used to deposit the front contact layer.

The next step in the process is to apply an amorphous silicon-containing thin film semiconductor. The following will describe the application of a single junction semiconductor, however, the invention is not so limited. The amorphous silicon semiconductor comprises a p-i-n or preferably a n-i-p amorphous silicon thin film layers with a bandgap suitably ranging from about 1.4 eV to 1.75 eV, usually 1.4 to 1.6 eV. The amorphous silicon-containing thin film semiconductor can comprise hydrogenated amorphous silicon, hydrogenated amorphous silicon carbon or hydrogenated amorphous silicon germanium. The positively doped (p-doped) amorphous silicon p-layer of the amorphous silicon semiconductor is deposited on the front contact. The p-layer can be positively doped with diborane (B₂ H₆), BF₃ or other boron-containing compounds. An amorphous silicon, undoped, active intrinsic i-layer is deposited on the p-layer and a negatively doped (n-doped) amorphous silicon n-layer is deposited on the n-layer. The n-layer is positioned on the i-layer and can comprise amorphous silicon carbon or amorphous silicon negatively doped with phosphine (PH₃) or some other phosphorous-containing compound.

After the p-type layer has been formed to a thickness on the order of about 30 Å to about 250 Å, preferably less than 150 Å, an intrinsic, layer is applied. The intrinsic layer is applied to a thickness suitably on the order of about 1,500 to about 10,000 Å, preferably about 2,500 to about 4,500 Å. After the intrinsic layer is applied an n-doped layer is applied. An n-type dopant, such as phosphine (PH₃), is added to, for example, a silane feed in order to form an n-type amorphous silicon layer suitably having a thickness of about 100 Å to about 400 Å, preferably less than 150 Å.

The amorphous silicon layer i-layer is suitably deposited at a rate of about 1 Å. per second to about 200 Å thickness per second, more preferably at a rate of about 2Å per second to about 100 Å per second, when the substrate is moving by the source of the silicon at a rate of about 0.1 meter per minute meter to about 4 meters per minute, more preferably about 1 meter per minute to about 2 meters per minute. The amorphous silicon p- and n-layers are suitably deposited at a rate of about 2 Å per second to about 50 Å thickness per second, more preferably at a rate of about 4 Å per second to about 10 Å per second, when the substrate is moving by the source of the p- or n- doped silicon at a rate of about 0.1 meters per minute meter to about 4 meters per minute, more preferably about 1 meter per minute to about 2 meters per minute. It is preferable to deposit the amorphous silicon layers at a temperature of about 50° C. to about 400° C., more preferably about 100° C. to about 300° C., and at a pressure of about 1 milliTorr to about 5 Torr, more preferably about 4 millitorr to about 2 Torr.

The amorphous silicon layers are suitably deposited on the substrate by one or more methods that can be used to continuously provide uniform layers of amorphous silicon on the substrate as it moves by the source. For example Plasma Enhanced Chemical Vapor Deposition (PECVD) and LPCVD) can be used. Other methods for continuously depositing the amorphous layers include deposition using electron cyclotron resonant microwaves, hot wire CVD, cascaded arc plasmas, dc hollow cathode, tuned antenna microwaves, or rf hollow cathode. One or more sputtering techniques (PVD) can also be use to apply the amorphous semiconductor silicon layers having a p-i-n junction. Depending on the method used to deposit the amorphous layers different feeds can be used. For example, for the glow discharge type of methods, silane and silane/hydrogen mixtures can be used. With PVD solid silicon along with an argon/hydrogen mixture can be used. For hollow cathode technique, a silicon target and silane, or silane and hydrogen can be used.

The next step in the process is to remove strips of the amorphous silicon layers parallel to the strips formed in the front contact. However, prior to adding these strips, it is preferable to add a first layer of the back contact, preferably a transparent conductive oxide such as zinc oxide, tin oxide, or indium-tin oxide to the amorphous layers. Preferably it is zinc oxide. This zinc oxide or other CTO layer such as indium-tin-oxide, cadmium stannate, or tin oxide is preferably applied to a thickness of about 600 Å to about 2,000 Å more preferably about 800 Å to about 1,400 Å at a rate of about 10 Å per second to about 200 Å per second, more preferably at a rate of about 20 Å per second, to about 100 Å per second thickness when the substrate is moving by the source of oxide at a rate of about 0.1 meter per minute meter to about 4 meters per minute, more preferably about 1 meter per minute to about 2 meters per minute. The temperature of the deposition of the zinc oxide is suitably about 120° C. to about 250° C., preferably about 140° C. to about 200° C. and most preferably about 175° C. to about 195° C. The pressure for the deposition is suitably about 1 milliTorr to about 10 Torr, preferably about 2 milliTorr to about 3 Torr and most preferably about 4 milliTorr to about 2 Torr. The first layer of the back contact, if used, is suitably applied by reactively sputtered zinc, preferably doped with aluminum or boron using pulsed power supplies to ensure uniform cathode properties. Other methods for applying the first layer of the back contact can also be used such as LPCVD, AC sputtering or rf sputtering.

After the deposition of the first layer of the back contact, or if such a first layer is not deposited, the amorphous layer is treated to remove strips of the amorphous silicon layers. The amorphous silicon semiconductor material and first layer of back contact, if present, are removed in strips which are spaced from but generally parallel to the strips of conducive oxide removed from the first conductive layer. For example, these strips or scribes can be about 30 micrometers to about 150 micrometers wide, preferably from about 40 micrometers to about 80 micrometers wide and suitably spaced about 25 micrometers to about 150 micrometers, more preferably about 25 micrometers to about 100 micrometers from the strips of removed first conductive layer.

To form these strips in the amorphous layer, the amorphous layer can be removed by any suitable method such as laser ablation, chemical etching or mechanical scribing. However, in the continuous or semicontinuous process of this invention the strips of amorphous silicon semiconductor are suitably removed by laser scribing. In this method, one or more laser beams are directed at the amorphous silicon layer and scanned across its surface in the desired pattern thereby removing the amorphous silicon layers but not the conductive oxide of the front contact.

The laser selected as well as the wavelength of the laser light, the pulse-width of the laser, the laser beam shape and the repetition rate are selected to efficiently remove the amorphous silicon layer in the desired areas to form the strips or scribes. For example, the laser can be a Nd:YAG laser operating at a wavelength of about 532 nanometers. The laser used suitably has a pulse-width of about 1 nanosecond to about 500 nanoseconds, more preferably of about 5 nanosecond to about 100 nanoseconds, a repetition rate suitably of about 10 KHz to about 400 KHz more preferably about 30 KHz to about 200 KHz, a beam shape that is suitably Gaussian, top hat, or delta function. Preferably it is Gaussian. It is preferable to scan the amorphous layer at a rate that is about 0.1 meters/second to about 50 meters/second, more preferably about 0.8 meters/second to about 20 meters/second. At these scanning rates, the amorphous layer can be removed to form the strips or scribes in a time period that is suitable for the continuous or semi-continuous processes of this invention.

In the preferred process of this invention, the laser scribing to form the strips or scribes in the amorphous layers is conducted at the same or about the same temperature and at the same pressure or about the same pressure as the temperature and pressure used to deposit the front contact layer.

The next step in the process is preferably the deposition of the rear contact. Generally, the rear contact is one or more highly conductive metals such as silver, molybdenum, platinum, steel, iron, niobium, titanium, chromium, bismuth, antimony, or preferably aluminum. The rear contact can be deposited by one or more methods for applying a thin film of metal such as PVD, LPCVD or evaporation. Preferably, however, the rear contact is applied using a magnetron sputtering technique, preferably from a rotary magnetron source. The rear metal contact is applied to a thickness that is suitably about 1,000 Å to about 5,000 Å, preferably about 2,000 Å to about 3,000 Å, and most preferably about 2,000 Å to about 2,400 Å. The deposition of the rear metal contact is preferably done at a temperature of about 20° C. to about 250° C., more preferably about 50° C. to about 200° C. and most preferably at a temperature of about 100° C. to about 175° C. The pressure for the deposition of the rear metal contact is suitably about 0.2 milliTorr to about 10 milliTorr, preferably about 1 milliTorr to about 5 milliTorr. The rear metal contact is suitably applied at a rate of about 10 Å/second to 1,000 Å/second thickness, preferably at a rate of about 50 Å/second to about 500 Å/second and most preferably at a rate of about 100 Å/second to about 200 Å/second when the substrate is moving by the source of the back metal contact at a rate of about 0.1 meter per minute to about 4 meter per minute, more preferably about 1 meter per minute to about 2 meters per minute. The deposition of the metal rear contact provides for a uniform metal coating or layer over the entire surface of the amorphous layers which optionally have a CTO layer deposited thereon. When the metal rear contact is deposited it fills the strips or scribes in the amorphous layers thereby forming a conduit or interconnect with the front contact.

The next step in the process is to remove strips of the back metal contact to form the individual cells of the photovoltaic device. The back contact layer is removed in strips or scribes which are spaced from but generally parallel to the strips or scribes in the amorphous semiconductor material. The strips of back contact metal can be about 30 micrometers to about 150 micrometers wide, preferably from about 40 micrometers to about 80 micrometers wide and suitably spaced about 25 micrometers to about 100 micrometers, preferably from about 40 micrometers to about 80 micrometers from the strips in the amorphous semiconductor layer. To form these strips in the back contact metal layer, the metal layer can be removed by any suitable means. However, in the continuous or semicontinuous process of this invention, the strips of the metal layer are suitably removed by laser scribing. In this method one or more laser beams are directed at the metal layer and scanned across it surface in the desired pattern thereby removing the metal layers. Methods for removing the back contact layer using a laser process are described in U.S. patent application Ser. No. 091891/752 and PCT/US 01/20398 which are incorporated herein by reference in their entirety. In addition to disclosing the method of forming the laser scribes in the back contact, it also describes the dimensions of the laser scribes. That patent application also describes a method for forming in the back contact a series of scribes that impart partial transparency to the photovoltaic device or imparting designs. Such laser scribing methods described therein can also be use in the continuous or semicontinuous process of this invention.

The process of this invention is preferably carried out in the continuous mode. In that mode, the substrate, preferably a flat glass substrate and preferably a low iron glass, is moved or carried along (the substrate positioned vertically or horizontally) a conveying system, for example rollers, through a series of deposition chambers where the various layers of the photovoltaic device as described above are deposited on the substrate. In order to enhance the speed of the process the substrate is moved through the different deposition steps at the same or about the same temperatures and preferably at the same or about the same pressures. For example, ±2 to 25° C., or ±2 to 10° C., or ±1-5° C. and ±20 Torr or ±10 Torr or ±5 Torr. In this manner it is not necessary to repeatedly cool and then reheat the substrate which would be time consuming and energy inefficient. In addition, in the continuous process of this invention the scribing steps to scribe the front contact and the amorphous layers, which are preferably accomplished by laser scribing, are also accomplished while the substrate and the conducive and semiconductor layer deposited thereon are at an elevated temperature and at the reduced pressures preferably used for the deposition procedures as described above.

For example, the zinc oxide deposition of the front contact, laser scribe of the front contact, deposition of the p, i and n amorphous silicon layers, laser scribe of the amorphous silicon layers, and zinc oxide deposition of the first layer of the back contact can occur at a temperature of about 180 to about 200° C. and at a pressure in the range of about 0.1 to about 2 Torr. The deposition of the aluminum back contact layer can occur at a temperature of about 150° C. but at a pressure of about 0.002 to 0.01 Torr. Thus, all the deposition steps and the laser scribing steps that take place between the deposition steps all occur at an elevated temperature within a certain range and all occur at a reduced pressure thereby elimination the need for rapidly cooling or rapidly reheating the substrate.

In the process of this invention the chambers used to deposit the various layers of the photovoltaic device and the chambers used for the laser scribing steps at low pressure as described herein may be cylindrical in geometry, which provides strength for the low-pressure operations. A cylindrical geometry also provides for uniform heating of the substrates. Other geometries can be used, however. The temperature of the substrates is preferably measured using non-contact infrared thermocouple arrays.

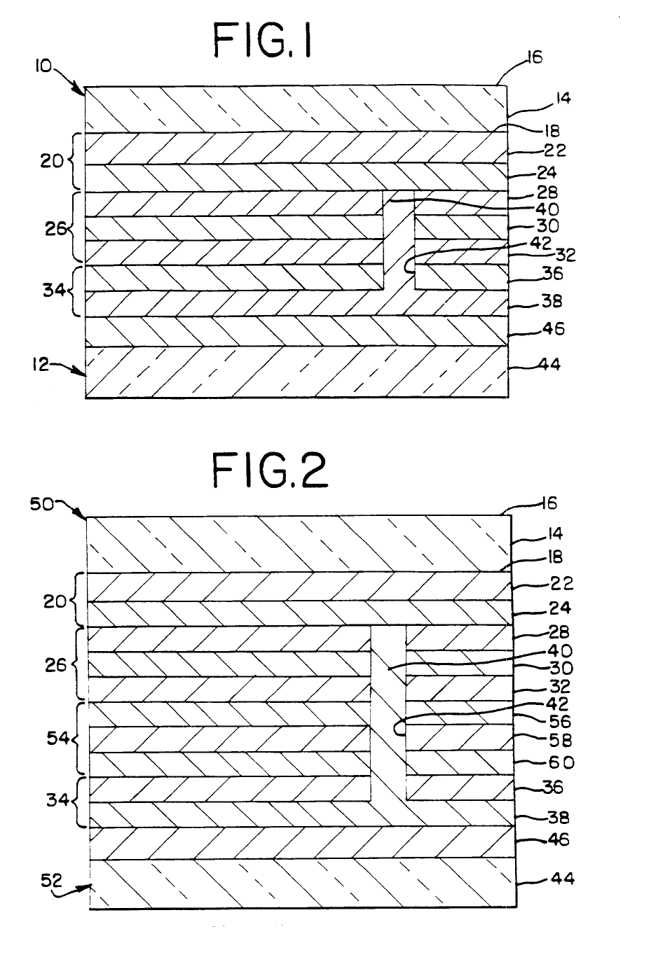

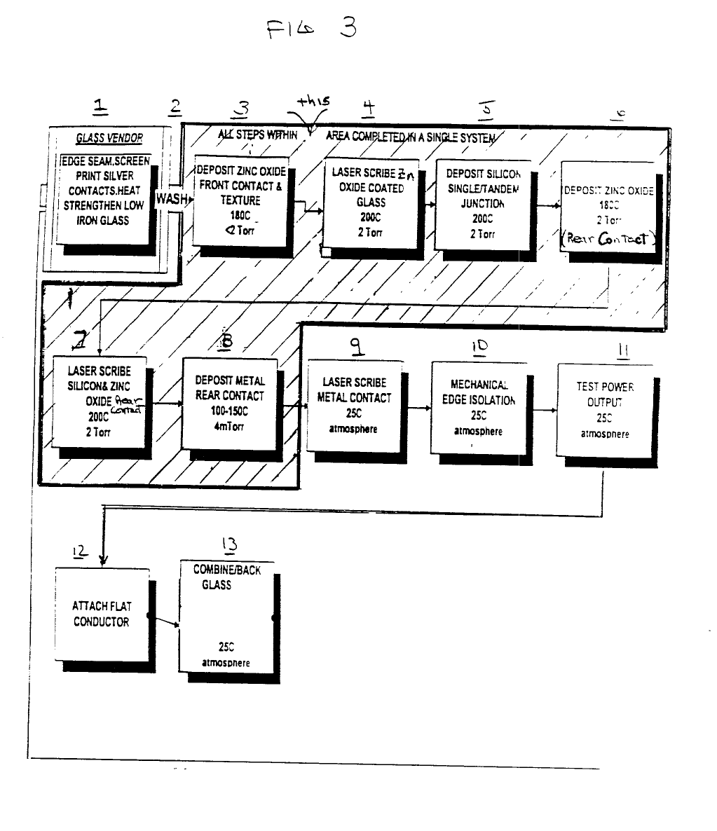

FIGS. 1 and 2 show in cross-sectional form, solar cells (photovoltaic devices) that can be made by this invention. FIG. 1 shows a single junction device and FIG. 2 shows a tandem junction device. The monolithic photovoltaic (PV) module 10 of FIG. 1 provides a photovoltaic device, which comprises a single junction solar cell 12. The solar cell has a generally flat substrate 14 made of transparent glass, which provides the front glass of the photovoltaic module. The substrate has an external outer (outside) surface 16 and an inwardly facing inner surface 18. The substrate comprises a low-iron glass.

A dual layer front contact 20 lies upon the substrate comprising an optional dielectric outer front layer 22 comprising silicon dioxide positioned upon the inner surface of the substrate and transparent zinc oxide inner back (rear) layer 24 positioned upon the optional dielectric layer.

An amorphous silicon-containing thin film semiconductor 26 (FIG. 1) provides a single junction solar cell. The amorphous silicon semiconductor solar cell comprises a p-i-n or preferably an n-i-p amorphous silicon thin film semiconductor with a bandgap ranging from about 1.4 eV to 1.75 eV, usually to 1.6 eV. The amorphous silicon semiconductor or segment can comprise: hydrogenated amorphous silicon, hydrogenated amorphous silicon carbon or hydrogenated amorphous silicon germanium. The positively doped (p-doped) amorphous silicon p-layer 28 of the amorphous silicon semiconductor is deposited on a zinc oxide layer of the front contact. The p-layer can-be positively doped with diborane (B₂ H₆), BF₃ or other boron-containing compounds. An amorphous silicon, undoped, active intrinsic i-layer 30 is deposited upon the p-layer, and a negatively doped (n-doped) amorphous silicon n-layer 32 is deposited on the i-layer and can comprise amorphous silicon carbon or amorphous silicon negatively doped with phosphine (PH₃) or some other phosphorous-containing compound.

A dual layer rear contact (back contact) contact 34 (FIG. 1) is deposited upon the amorphous silicon n-layer of the solar cell 26. The inner metallic front layer 36 of the rear contact can comprise a transparent zinc oxide. The outer metallic rear (back) layer 38 of the rear contact can comprise a metal, such as silver or preferably aluminum.

An interconnect 40 (FIG. 1) provides an electrical contact between the zinc oxide layer of the front contact and the metal outer layer of the rear contact. The interconnect extends through a trench (hole) 42 in the semiconductor and the zinc oxide inner layer of the rear contact.

A transparent superstrate 44 (FIG. 1) comprising glass can be positioned upon the back (rear) contact of the photovoltaic module and device. The photovoltaic module can be encapsulated with an encapsulating material (encapsulant) 46, such as ethylene vinyl acetate (EVA), to help protect the photovoltaic module from the environment.

The monolithic module 50 of FIG. 2 provides a photovoltaic device, which comprises a tandem junction solar cell 52. The dual junction solar cell of FIG. 2 is generally structurally, physically and functionally similar to the single junction solar cell of FIG. 1, except as explained below. For ease of understanding, similar components and parts of the solar cells of FIGS. 1 and 2 have been given similar part numbers, such as substrate 14, front contact 20 with outer dielectric layer 22 and inner zince oxide layer 24, amorphous silicon-containing thin film semiconductor 26 which provides front solar cell or segment, dual layer rear contact (back contact) 34 with a zinc oxide inner metallic layer 36 and an outer metallic layer 38, interconnect 40, trench 42, superstrate 44 EVA 46, etc. The n-i-p rear solar cell has n, I, and players, which are arranged as previously explained. The n, i, and p-layers of the rear cell are sometimes referred to as the n₁-, i₁- and p₁-layers, respectively, of the rear cell. A rear (back) solar cell 54 comprising an amorphous silic,on-containing thin film semiconductor is sandwiched and positioned between and operatively connected to the front cell and the rear (back) contact. The rear amorphous silicon cell can be similar to the front amorphous silicon cell described above. The amorphous silicon positively doped p₂-layer 56 of the rear cell is deposited on the amorphous silicon negatively doped n₁-layer 32 of the front cell. The amorphous silicon intrinsic i₂-layer 58 of the rear cell is between the n₂-layer 60 and p₂-layer 56 of the rear cell.

In multi-junction (multiple junction) solar cells, such as the tandem junction solar cells of FIG. 2, the i-layers of the amorphous silicon containing cells can comprise an active hydrogenated compound, such as amorphous silicon, amorphous silicon carbon or amorphous silicon germanium. The active p-layers of the amorphous silicon-containing cell can comprise a p-doped hydrogenated compound, such as p-doped amorphous silicon, p-doped amorphous silicon carbon or p-doped amorphous silicon germanium. The active n-layers of the amorphous silicon-containing cell can comprise an n-doped hydrogenated compound, such as n-doped amorphous silicon, n-doped amorphous silicon carbon or n-doped amorphous silicon germanium.

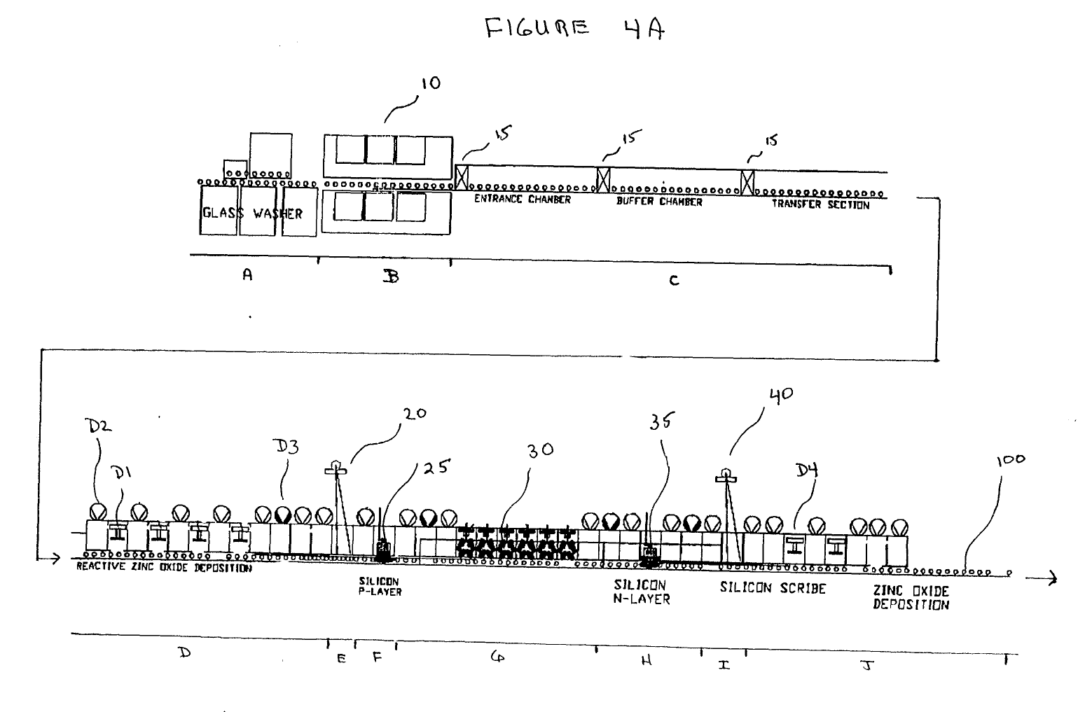

FIG. 3 shows in block diagram form a preferred embodiment of the process of this invention.

In step 1 of FIG. 3 the glass in the selected size obtained from a vendor is edge seamed and a conductive frit paste applied for the electrical conduit or so called, “bus bars”. The glass, preferably a low-iron glass, is heated to about 600° C. to cure the frit and to heat strengthen the low-iron glass. In step 2 the glass is washed to remove debris. In step 3 the zinc oxide front contact is deposited and textured. The temperature for the deposition and texturing is about 180° C. and the pressure is about 2 Torr. Preferably the zinc oxide is deposited by LPCVD or by sputtering. In this step the zinc oxide is also textured by reactive ion etching. In step 4 the zinc oxide front contact is laser scribed using a Nd:YVO₄ laser while the glass is maintained at about 200° C. and a pressure of 2 Torr. For this laser-scribing step, the laser mechanism is protected from the environment of the chamber where the laser scribing is taking place. Preferably the laser is operated from outside of the chamber whereby the laser light passes through a window in the chamber, the window being made of quartz. In order to protect the window from being coated with the vaporized zinc oxide it is necessary to have a sweep gas pass over the surface of the window that is inside the chamber. Alternatively, a condenser can be placed near the window to preferentially condense the zinc oxide before it reaches the window surface. In another embodiment, the window can be repeatedly and rapidly changed by sliding or swinging another window in its place without substantial loss of vacuum. With this method, a partially obscured window can be removed, cleaned and replaced without interrupting the process. In step 5 the amorphous silicon p, i and n layers of the photovoltaic device are deposited in sequence on the front contact. This deposition step is accomplished at 200° C. and at a pressure of about 2 Torr. The deposition of the p, i, and n layers is accomplished using one or more techniques such as electron cyclotron resonant microwaves, hot wire CVD, cascaded arc plasmas, rf hollow cathode, or DC cathodic, in order to form the desired uniform layer of the amorphous silicon on the substrate. Since the p, i and n layers each have different chemical composition and are generally formed using different compositions of feed materials such as silicon hydride, diborane, methane, and phosphine, it is preferable to isolate the different regions in the deposition process so that feed materials used for the deposition of one layer do not contaminate the feed materials of the other layer. Such isolation is accomplished by one or more suitable techniques. For example, between each deposition region of the process, the gases present are pumped out using vacuum pumps with sufficient pumping to prevent the gases from entering an adjacent deposition region. A buffer region can also be used to separate the different deposition regions and this buffer region can be pumped out as described above or swept with an appropriate inert gas to remove any contaminating gasses. Such a vacuum pumping technique or the buffer region with the vacuum pumping or inert gas sweep can also be used to separate the region where the zinc oxide layers are deposited from the regions where the amorphous silicon layers are deposited.

In step 6 the zinc oxide layer of the back (rear) contact is deposited. The zinc oxide is deposited at about 180° C. and at a pressure of about 2 Torr. The preferred method of depositing this zinc oxide layer is to use reactively sputtered zinc either doped with aluminum or boron using pulsed power supplied to the cathode to insure uniform cathode properties and uniform deposition. In step 7 of the process the amorphous layers and the zinc oxide layer of the back contact are laser scribed using, preferably, a Nd:YVO₄ laser. These laser scribes, as described above, reach through the zinc oxide layer of the back contact and through the amorphous silicon layers but do not scribe the front contact layer. The arrangement for the laser scribing in this step is the same as described in step 4 whereby the laser and the laser controls are outside of the chamber containing the substrate held at about 200° C. and a pressure of 2 Torr. Similarly as described in step 4 above, the window through which the laser beams or beams enter the chamber needs to be protected from having the material which is removed during the scribing depositing on and obscuring the path of the laser beam. In step 8 the metal layer, preferably aluminum, is deposited at a temperature of about 100-150° C. and at about 4 milliTorr (0.004) Torr pressure. A rotary magnetron is the preferred source of the aluminum rear contact. This step can also include an annealing step to anneal the rear metal contact. If such a heat annealing step is used, it is preferably accomplished using an in-line infrared source in cylindrical configuration immediately after the metal deposition step and at the same pressure. In step 9 the rear metal contact layer is scribed at ambient pressures and temperatures to isolate each cell in the photovoltaic device and, if the photovoltaic device is to be made partially transparent or have other additional scribing of the rear metal contact, it is accomplished in this step. The scribing is preferably accomplished using a Nd:YVO₄ laser. After the laser scribing, the photovoltaic device is preferably washed, preferably ultrasonically to remove any debris that was formed by the laser scribing of the metal layer. In step 10,a narrow strip of the metal and other layers deposited are removed around the perimeter of the photovoltaic device to “edge-isolate” the photovoltaic device. The strip for the edge isolation is generally placed about 0 to about 20 cm from the edge of the device for most applications. In step 11 the device is tested for power output. If satisfactory, connectors are attached in step 12 so the device can be connected to the system in which it will be used. In step 13, a second panel of glass is sandwiched on to the photovoltaic device preferably using a polymeric material between the plates of glass to seal and protect the photovoltaic elements.

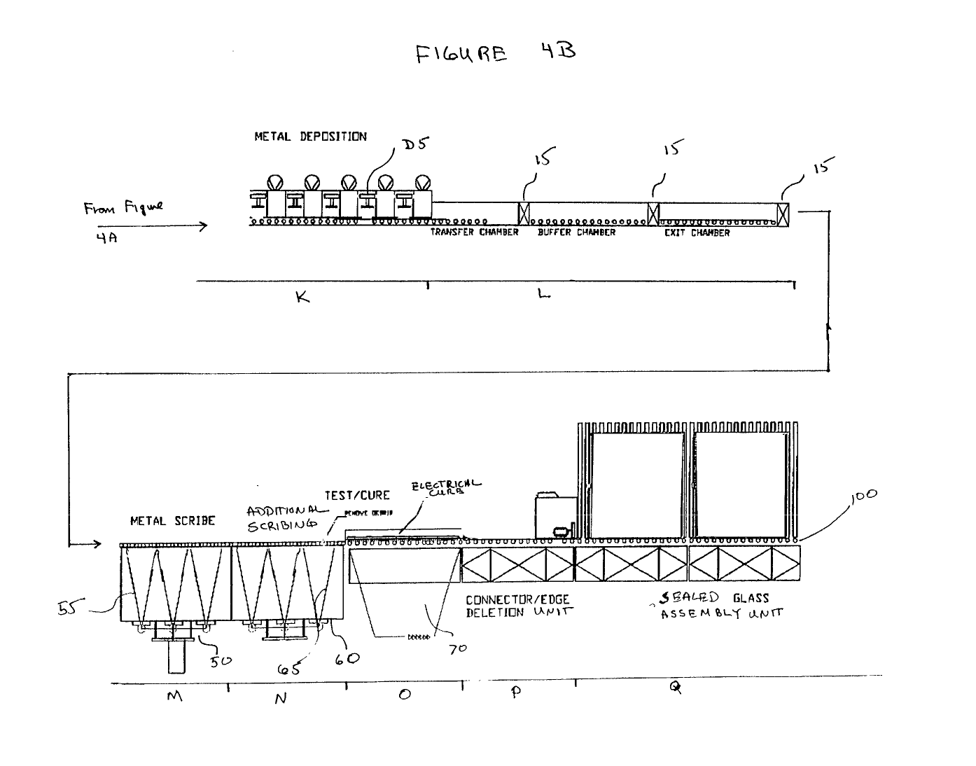

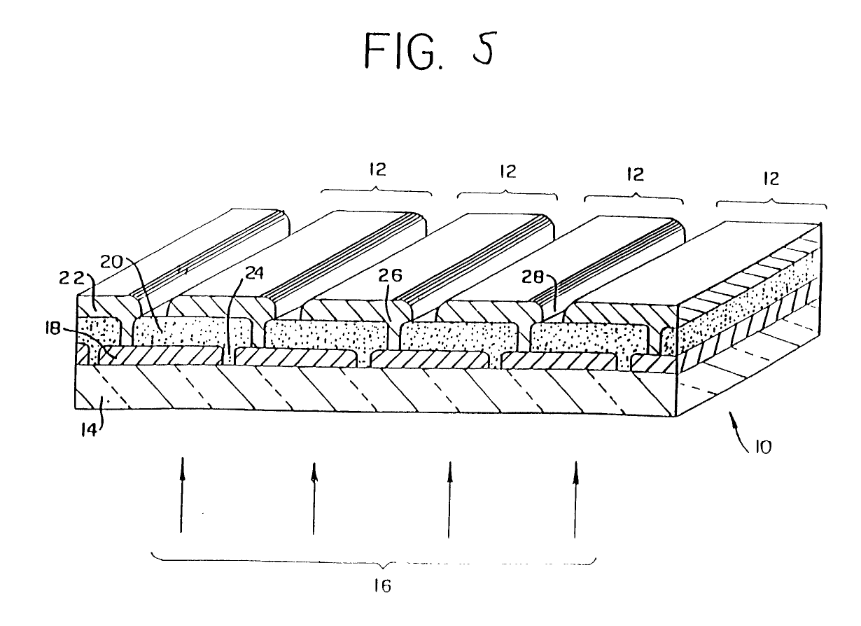

FIG. 4a, which is continued on FIG. 4b, shows in schematic form a preferred embodiment of this invention. In this figure section A is a washing station where the glass substrates of various sizes are washed in the glass washer unit shown. In section B, the frit for the electrical connections (i.e., bus bars) is applied and then the glass plate with the frit is heated in a furnace 10 to cure the frit, anneal the glass and raise the glass substrate to the process temperature. Section C is a transition region where the glass substrate is given time to equilibrate in temperature and enter into the evacuated (low pressure) sections of the process. In this transition section C, vacuum pumps are present (not shown in the figure) to provide for and maintain a low pressure. This section also contains a “gate means” such as slit valves 15 which are a means to prevent atmospheric gasses from entering the low-pressure regions and thereby permitting the formation of a vacuum in the low-pressure process areas yet still provide for the passage of the substrate from one region or part of the process to the next. As shown in FIG. 4a and 4b the transition section C contains three sections: and entrance chamber, a buffer chamber and a transfer chamber. In front of the entrance chamber and between each chamber in transition section C is positioned a slit valve to provide some degree of isolation between the regions and therefore provide for a more efficient, staged progression from atmospheric to low-pressure regions of the process. A final slit valve or other type of gate means separates the transfer section from the next step in the process. In section D, the front contact made from zinc oxide is deposited on the substrate using zinc oxide sputtering. Other means for depositing the front contact can be used. As shown in the figure, multiple zinc oxide sources (D1) and multiple vacuum pumps (D2) are employed as the glass substrate moves under the sources and by the pumps. In FIG. 4a and 4b, all parts depicted in the same manner as D1 represent a means for depositing a material on the substrate, such as zinc oxide or aluminum metal. All parts depicted in the same manner as D2 represent vacuum pumps. The zinc oxide layer may be subsequently etched by reactive ion etching. In section E the zinc oxide front contact is laser scribed using laser and high speed laser scanning unit 20 to start the formation of the series of parallel scribes and electrical interconnects which separate the photoelectric device into a series of electrically connected cells As shown in the figure, the laser is directed from above for this scribing step. Gas isolation blower D3 or other equivalent means may be used between sections D and E to reduce the transfer of material in the gas phase or in particulate form from section D to section E. Other means for preventing such transfer or contamination can also be used. In FIG. 4a and 4b, all parts depicted the same as D3 are also gas isolation blowers or other means to reduce the transfer of gas phase or particulate materials between the regions separated by such gas blowers. In section F the amorphous silicon p layer is deposited by a dc glow discharge unit 25 such as a pulsed DC PECVD unit. Other means for deposition the amorphous silicon p layer can be used. In section G the intrinsic or i layer of amorphous silicon is deposited by tuned antenna microwave glow discharge units 30, although other means for depositing the amorphous silicon I layer can be used. In section H the amorphous silicon n layer is deposited by a dc glow discharge unit 35 such as a pulsed DC PECVD unit. Other means for deposition the amorphous silicon n layer can be used. In section I the amorphous silicon layers are laser scribed using laser and high speed laser scanning unit 40 to form the grooves or scribes for the interconnects between the front contacts and the rear contacts. In section J the first layer of the rear contact, such as a zinc oxide layer, is deposited by low-pressure vapor deposition units D4. Other means for such deposition can be used. In section K the metal layer, such as aluminum, of the rear contact is deposited by PVD units D5 or other means for depositing a metal rear contact or back contact layer. In section L the photovoltaic device is cooled and the pressure increased to ambient. This section will also has “gate means” 15 such as slit valves to separate the low pressure section from the atmospheric pressure section. Section L is shown as having a transfer chamber, a buffer chamber and an exit chamber. Each chamber being separated by the gate means such as slit valves or other means for separating a low pressure section or region from a higher pressure section or region and still permit the passage of the substrate between such sections or regions. In section M the back contact layer of the photovoltaic device having the zinc oxide and metal layers is again subjected to laser scribing using laser scribing unit 50 to complete the formation of the scribe lines that separate the device into a series of individual series connected cells. In section N optional laser scribing is accomplished using laser scribing unit 60 if a partially transparent photovoltaic device is desired or if a pattern on the photovoltaic device is desired as described, for example, in U.S. patent application Ser. No. 09/891,752 and in PCT Patent Application PCT/US, 01/20398. As shown in FIG. 4b the scribing in sections M and N by laser beams 55 and 65 is accomplished from beneath the substrate. During this part of the process, the substrate being scribed is held by a means for supporting the substrate such as a frame or a glass plate to permit the laser beams 55 and 65 to impinge upon the substrate and layers to be scribed. In section 0 the photovoltaic device is subjected to a reverse bias electrical shunting using reverse bias shunting unit 70 to electrically cure any defects in the device. In section P, the photovoltaic device is edge-scribed and an electrical connector is added. In section Q the device is sealed with another piece of substrate material such as glass to form the completed, sealed photovoltaic device. In such sealing unit the substrate can be sealed to a second sheet of substrate material by positioning a sheet or layer of sealant material such as poly ethylene vinyl acetate between the sheets and heating the assembly to soften or melt the sealant material and then pressing the sheets together to form the seal. Alternatively, the substrate sheet can be sealed to a second sheet of substrate material using an edge seal and leaving a space between the sheets.

As shown in FIG. 4a and 4b, the entire process is continuous once the glass substrate of the desired dimensions is loaded onto the conveyor means at the beginning of the process. The conveying means can be any suitable means for transporting or conveying the glass substrate through the different process sections. Mechanically driven rollers (shown as 100 in FIGS. 4a and 4b.) made from an inert and durable materials such as stainless steel, aluminum and fused silica are preferred. All of the chambers shown in FIGS. 4a-4b in sections C-L and particularly D-K, for example, the chambers surrounding the various deposition equipment and laser scribing areas, are preferably low-pressure chambers designed to establish and maintain the low pressures as described herein that may be used for the various deposition and laser scribing steps described herein. The substrate can move through the process horizontally or vertically or near-vertically (±10°). Although this process has been described using a single junction amorphous thin film photovoltaic device, the invention is not limited. The device can be single, double, triple junction. Multiple junction devices having more than three junctions are also possible. In addition, the invention is not limited to amorphous silicon layers. Microcrystalline layers and layers containing materials other than silicon can also be used. If such devices are made by the process of this invention, additional deposition sections can be added. The process of this invention can be adapted easily to such other photovoltaic devices by simply adding another module to accomplish the desired deposition. In the preferred apparatus used in the method of this invention, the different sections used to deposit the desired layers are modular so they can be added or deleted from the apparatus so the overall apparatus can be readily adapted to different configurations of the layers in the photovoltaic devices manufactured Descriptions of different junction and layers for photovoltaic devices and methods for forming interconnects useful in the process and photovoltaic devices of this invention are described in U.S. Pat. Nos. 6,077,722 and 5,246,506, which are hereby incorporated by reference in their entirety.

FIG. 5 shows in perspective view a photovoltaic module that can be made by this invention showing how the strips or laser scribes form the individual cells and interconnects in a single junction photovoltaic device. In this FIG. 5, 10 is the photovoltaic device, 12 are the individual cells, 14 is the glass substrate, 16 represents light, 18 is the front, zinc oxide contact (silicon dioxide layer is not shown), 20 is the amorphous p-i-n junction layers, 22 is the metal back or rear contact (a zinc oxide layer for back content is not shown), 24 is the laser scribe of the zinc oxide front contact filled with amorphous silicon, 26 is the laser scribe through the amorphous silicon filled with metal from the back contact and 28 is the scribe in the back metal contact. Methods for scribing the various CTO, amorphous silicon, zinc oxide and metal back contact layers-suitable for use in the method of this invention are describe in U.S. Provisional Patent Application No. 60/346,327 filed on Jan. 7, 2002, which is incorporated herein by reference in its entirety. U.S. Provisional Patent Application No. 60/266,771 filed on Feb. 6, 2001 is incorporated herein by reference in its entirety.

That which is claimed is:

1. A process for making a photovoltaic device comprising depositing at least one thin film layer on a substrate by moving the substrate past one or more sources of material to be deposited, thereby forming on the substrate at least one thin film of the material.

2. The process of claim 1 wherein the material deposited comprises one or more of a transparent conductive oxide, amorphous silicon or a metal.

3. The process of claim 1 wherein the process is a continuous process.

4. The process of claim 1 wherein the process is a semi-continuous process.

5. The process of claim 1 comprising the steps of depositing a layer comprising a transparent conductive oxide layer, depositing at least one layer comprising amorphous silicon and depositing at least one layer comprising a metal, and wherein all the layers are deposited at a relatively similar elevated temperature and a relatively similar reduced pressure.

6. The process of claim 5 wherein the depositing steps are accomplished without the substrate cooling more than about 20° C. between each step.

7. The process of claim 6 wherein the depositing steps are accomplished without the pressure surrounding the substrate varying by more than about 10 Torr between each step.

8. The process of claim 1 further comprising laser scribing at least one layer.

9. The process of claim 5 further comprising laser scribing at least one layer.

10. The process of claim 9 wherein the laser scribing is conducted at about the same pressure and at about the same pressure used to deposit the layer scribed.

11 An apparatus for depositing at least one layer on a substrate to form a photovoltaic device comprising: a means for transporting the substrate, at least one deposition chamber, a means for depositing photovoltaically active layers on the substrate, means for depositing a front contact on the substrate, means for depositing a back contact on the substrate, wherein at least one of the depositing means can accomplish the deposition in a continuous manner as the substrate passes the depositing means.

12. The apparatus of claim 11 further comprising at least one laser for scribing at least one layer.

13. The apparatus of claim 12 further comprising a laser scribing chamber and wherein at least one laser is positioned outside the chamber and the chamber having a window to permit the passage of laser light beams into the chamber.

14. The apparatus of claim 11 wherein at least one of the depositing means is stationary.

15. The apparatus of claim 12 further comprising at least one laser scanner.

16. The apparatus of claim 11 wherein the deposition chamber is a low-pressure deposition chamber.

17. The apparatus of claim 13 wherein the laser scribing chamber is a low-pressure chamber.

18. A photovoltaic device formed by depositing one or more layers on a substrate wherein at least one of the layers is deposited in a continuous manner as the substrate passes a stationary means for depositing the layer.

19. The photovoltaic device of claim 18 comprising at least one amorphous silicon layer.

20. The photovoltaic device of claim 19 comprising at least one p-i-n junction.
